(19) United States
(12) Patent Application Publication
(10) Pub. No.: US 2012/0004872 A1
(43) Pub. Date: Jan. 5, 2012

(54) APPARATUS AND METHOD FOR ENERGY MANAGEMENT OF ELECTRIC DEVICES

(75) Inventors: Jung Hwan OH, Seoul (KR); Jae Seong PARK, Daejeon (KR); Dong Min SON, Suwon (KR)

(73) Assignee: LSIS CO., LTD.

(21) Appl. No.: 13/165,715

(22) Filed: Jun. 21, 2011

(30) Foreign Application Priority Data
Jul. 2, 2010 (KR) 10-2010-0064098

(51) Int. Cl. G06F 19/00; G01R 21/00

(52) U.S. Cl. 702/62

(57) ABSTRACT

Disclosed is an apparatus and method for energy management of electric devices, which individually displays various pieces of energy related information, such as consumption time, power consumption amount, current electricity rate and future electricity rate, in an apparatus provided to each electric device and controls the presence of operation of an individual electric device so as to make more effective use of limited energy resources in commercialized smart grid and smart meter technologies in which the energy price is changed depending on time. To this end, the operating state of each of the electric devices is estimated based on a variation in total energy consumption amount detected by a meter.

### CROSS-REFERENCE TO RELATED APPLICATION

This application claims the benefit of Korean Patent Application No. 10-2010-0064098, filed Jul. 2, 2010, the disclosure of which is hereby incorporated herein by reference in its entirety.

### BACKGROUND OF THE INVENTION

1. Field of the Invention

An aspect of the present invention relates to an apparatus and method for energy management of electric devices, and more specifically, to an apparatus and method for energy management of electric devices, which helps a user economically use electric energy by displaying energy related information of each operated electric devices using the electric energy in an energy consumption place, corresponding to an individual electric device.

2. Description of the Prior Art

Up to the present, various energies such as electricity, gas and water have been supplied according to the maximum demand, and the energy price has also been consistently maintained.

However, a plan for differentiating the energy price for each time zone or season has recently been conceived as a plan for more effectively using limited energy resources and reducing energy consumption.

A smart grid or a smart meter has come into spotlight as a technology for promoting an effective energy use.

The smart grid is a next-generation power network that can optimize energy efficiency and create a new added value by enabling customers to bidirectionally exchange real-time information with each other through combination of information technology (IT) with a power network.

The smart meter refers to a digital watt-hour meter to which a communication function is added. The smart meter can perform real-time examination of the amount of power used or bidirectional communication between a power provider and a customer.

Thus, the remote real-time inspection of a meter is possible without meterman's visiting a household, and hence the smart meter can precisely measure the used amount of power. Accordingly, the smart meter can obtain effects such as saving of metering cost and energy.

The smart grid society is changed into an environment in which electric power of an individual electric device can be controlled through a smart meter, an in home display and the like, and the price of electricity is changed depending on time. Therefore, a user tries to consume electric energy using a method most reasonable thereto.

In order to enable the user to actively control the consumption of electric energy, it is necessary that the user can conveniently and easily identify energy related information on energy consumption amount or electricity rate.

Since it is difficult to realize energy consumption situation only using integrated energy related information, it is necessarily considered to provide energy related information corresponding to an individual electric device.

### SUMMARY OF THE INVENTION

Embodiments of the present invention provide an apparatus and method for energy management of electric devices, in which energy related information for electric devices in an energy consumption place are displayed corresponding to an individual electric device, so that a user can more actually identify the consumption situation of electric energy and properly control the electric devices.

According to an aspect of the present invention, there is provided an apparatus for energy management of electric devices, the apparatus including: an energy related information display component attached to an outside or circumference of an individual electricity device; an estimation component configured to estimate an individual energy consumption amount based on an energy variation depending on time using a meter; an analysis component configured to analyze a power consumption amount of the individual electric device by analyzing a consumption time of the individual electric device; a first reception component through which the energy related information display component attached to the outside or circumference of the individual electric device receives individual energy related information of the individual electric device from the estimation component and the analysis component; and a switch component configured to determine whether or not an electric device is operated in the vicinity of the energy related information display component.

Preferably, the apparatus further includes a second reception component configured to receive electricity price information according to time from a central server.

Preferably, the meter includes a smart meter, and the smart meter may store energy consumption amount information of the individual electric device in a memory.

Functions of the estimation component and the analysis component are performed in the smart meter or the central server.

Preferably, the analysis component predicts at least one of current and future energy consumption rates of the individual electric device.

Preferably, the analysis component predicts the lifespan of the individual electric device.

Preferably, the energy related information display component is positioned in the vicinity of an on/off switch of the individual electric device.

According to an aspect of the present invention, there is provided a method for energy management of electric devices, the method including: displaying energy related information at an outside or circumference of an individual electricity device; estimating an individual energy consumption amount based on an energy variation depending on time using a meter; analyzing a power consumption amount of the individual electric device by analyzing a consumption time of the individual electric device; receiving individual energy related information of the individual electric device from the estimating and the analyzing in the displaying of the energy related information at the outside or circumference of the individual electric device; and determining whether or not an electric device is operated in the vicinity of the energy related information display component.

Preferably, the method further includes receiving electricity price information according to time from a central server.

Preferably, the estimating and the analyzing is performed in a smart server or the central server.

Preferably, the analyzing predicts at least one of current and future energy consumption rates of the individual electric device.

Preferably, the analyzing may predicts the lifespan of the individual electric device.

Preferably, the individual energy related information is communicated through a wireless communication scheme including at least one of RF, Zigbee and Bluetooth communication schemes. Preferably, the individual energy related information is communicated through a wired communication scheme using at least one of a general electric line, a power line, a LAN cable and a telephone line.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1 and 2 show embodiments of a system for energy management according to the present invention;

FIGS. 3 to 8 show examples illustrating a method for detecting an operating state of each electric device related to the present invention;

FIG. 9 shows an example of an energy price structure;

FIGS. 10 to 13 show various examples of a method for predicting a future energy consumption rate;

FIG. 14 shows an embodiment of a switch component;

FIG. 15 shows various examples of a path through which the switch component is controlled;

FIGS. 16 and 17 show an embodiment of an apparatus for energy management according to the present invention;

FIG. 18 shows an embodiment of the configuration of a meter;

FIG. 19 shows an example of information to be set in the meter;

FIG. 20 shows an embodiment of the configuration of a first reception component and a display component;

FIG. 21 shows an example for a use state of an apparatus for displaying energy related information; and

FIG. 22 shows an embodiment of a method for energy management according to the present invention.

### DETAILED DESCRIPTION OF PREFERRED EMBODIMENTS

Hereinafter, preferred embodiments of the present invention will be described in detail with reference to the accompanying drawings. However, the present invention is not limited to the embodiments but may be implemented into different forms. These embodiments are provided only for illustrative purposes and for full understanding of the scope of the present invention by those skilled in the art. Further, the terms used in the description are defined considering the functions of the present invention and may vary depending on the intention or usual practice of a user or operator. Therefore, the definitions should be made based on the entire contents of the description.

Energy refers to electric energy related to the present invention.

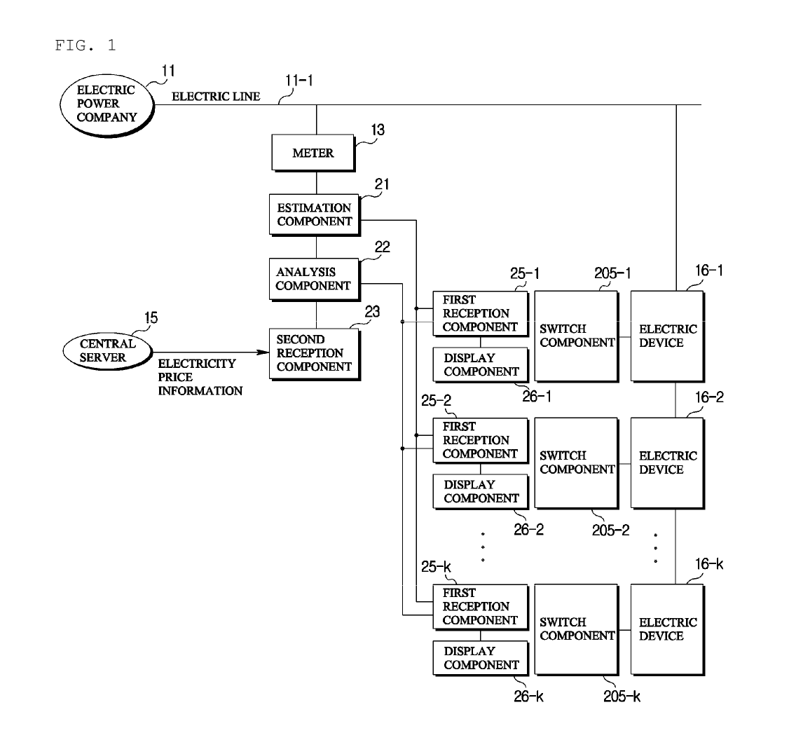

Referring to FIG. 1, electric energy supplied by an electric power company 11 is supplied to an energy consumption place along an electric line 11-1 so as to be used by various kinds of electric devices 16-1 to 16-k.

The electric devices refer to devices that operate using the electric energy, such as a refrigerator, a television (TV) set, a heating device, a cooling device and an illuminator.

A meter 13 is installed in the energy consumption place. The meter 13 refers to an electronic gauge that detects electric energy consumption information, such as energy consumption amount. A smart meter may be used as the meter 13.

A system for energy management according to the present invention includes at least an estimation component 21, an analysis component 22, first reception components 25-1 to 25-k, display components 26-1 to 26-k, and switch components 205-1 to 205-k.

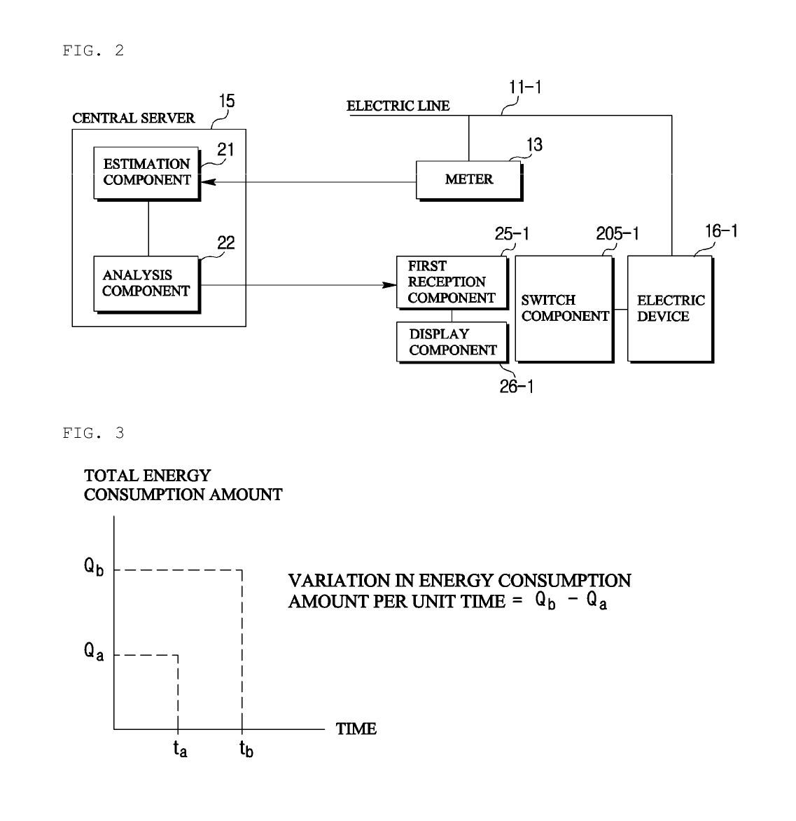

The estimation component 21 and the analysis component 22 may be configured to perform their functions in the meter 13 or to perform their functions in a central server 15 as shown in an example of FIG. 2.

The central server 15 is a server through which the electric power company 11 provides services related to energy. The central server 15 may transmit electricity price information through various communication networks such as a wireless mesh network, a power line communication network and an Internet network.

The display components 26-1 to 26-k are attached to outsides or circumferences of the respective electric devices 16-1 to 16-k so as to visually display energy related information. The first reception components 25-1 to 25-k receive the energy related information from the estimation component 21 and the analysis component 22.

The estimation component 21 and the analysis component 22 may communicate the energy related information of an individual electric device with the first reception components 25-1 to 25-k through various wireless or wired communication schemes.

RF, Zigbee or Bluetooth communication schemes and the like may be used as examples of the wireless communication scheme. In a case where the wired communication scheme is used, communication may be performed using a general electric line, electric power line, local area network (LAN) cable, telephone line, or the like.

The system may further include a second reception component 23 that receives electricity price information according to time from the central server 15.

Hereinafter, the estimation component 21, the analysis component 22, the first reception components 25-1 to 25-k, the display components 26-1 to 26-k, and the switch components 205-1 to 205-k in the system will be described in detail.

The estimation component 21 estimates an operating state of each of the electric devices, e.g., which electric device is under operation, based on an energy variation according to the time, detected by the meter 13.

To this end, the estimation component 21 maintains information on the energy consumption amount per unit time for each of the electric devices. The information on the energy consumption amount per unit time for each of the electric devices may be previously inputted in the manufacture of the system, or may inputted by a user.

In the latter case, the estimation component 21 may provide a user interface (UI) that enables the user to input the information on the energy consumption amount per unit time for each of the electric devices, or may receive information on the energy consumption amount per unit time for each of the electric devices, inputted by the user from another device.

In a case where the function of the estimation component 21 is performed in the meter 13, the meter 13 may be provided with a display screen, a key button and the like so as to provide the UI.

In a case where the function of the estimation component 21 is performed in the central server 15, the central server 15 enables the user to input information on energy consumption amount per unit time for each of the electric devices, used by the user, by performing interface with the user using various methods such as an Internet website and a call center.

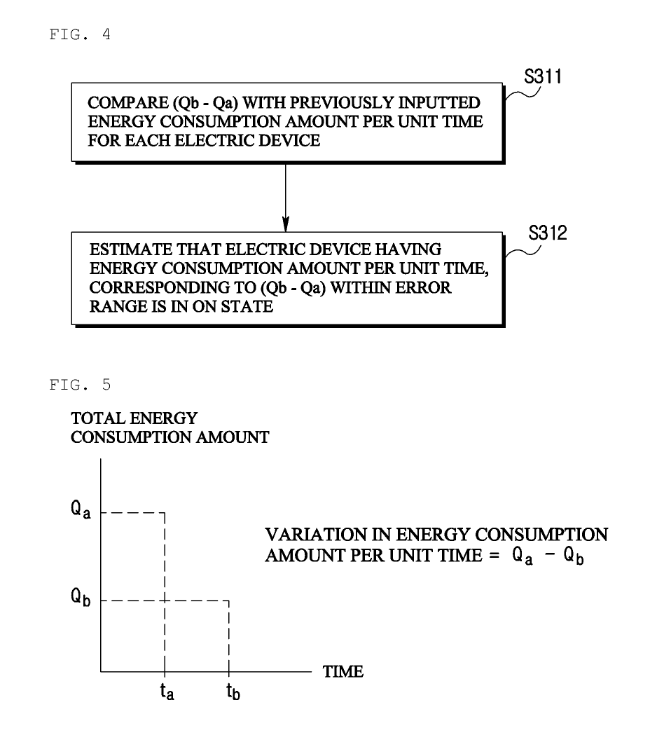

A method for estimating an operating state of each of the electric devices based on an energy variation according to the time detected by the meter 13 (specifically, the total energy consumption amount per unit time) will be described with reference to FIGS. 3 to 6.

Referring to FIG. 3, when the total energy consumption amount detected at a time ‘ta’ by the meter 13 is ‘Qa’, the total energy consumption amount detected at another time ‘tb’ by the meter 13 is ‘Qb’, and ‘tb−ta’ is a unit time, the variation in the total energy consumption amount per unit time becomes ‘Qb−Qa’. In this instance, Qb>Qa.

The variation in the total energy consumption amount per unit time means that the electric device under operation has been changed.

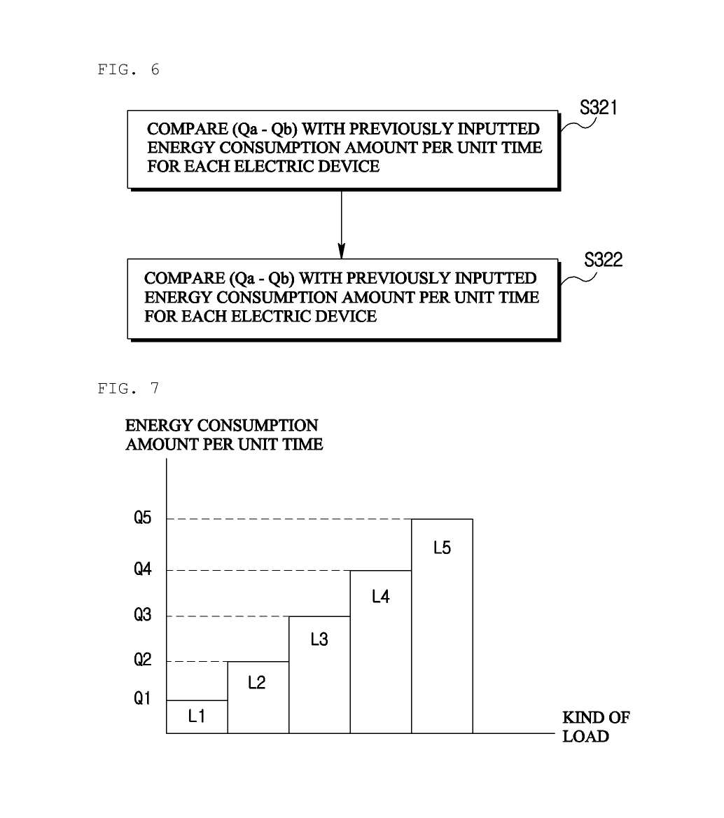

As shown in FIG. 4, the estimation component 21 compares the ‘Qb−Qa’ with information on the previously inputted energy consumption amount per unit time for each of the electric devices (S311). Then, the estimation component 21 searches for an electric device having an energy consumption amount per unit time, corresponding to the ‘Qb−Qa’ within an error range, and estimates that the corresponding electric device is in an OFF state and then changed into an ON state at the time ‘ta’ (S312).

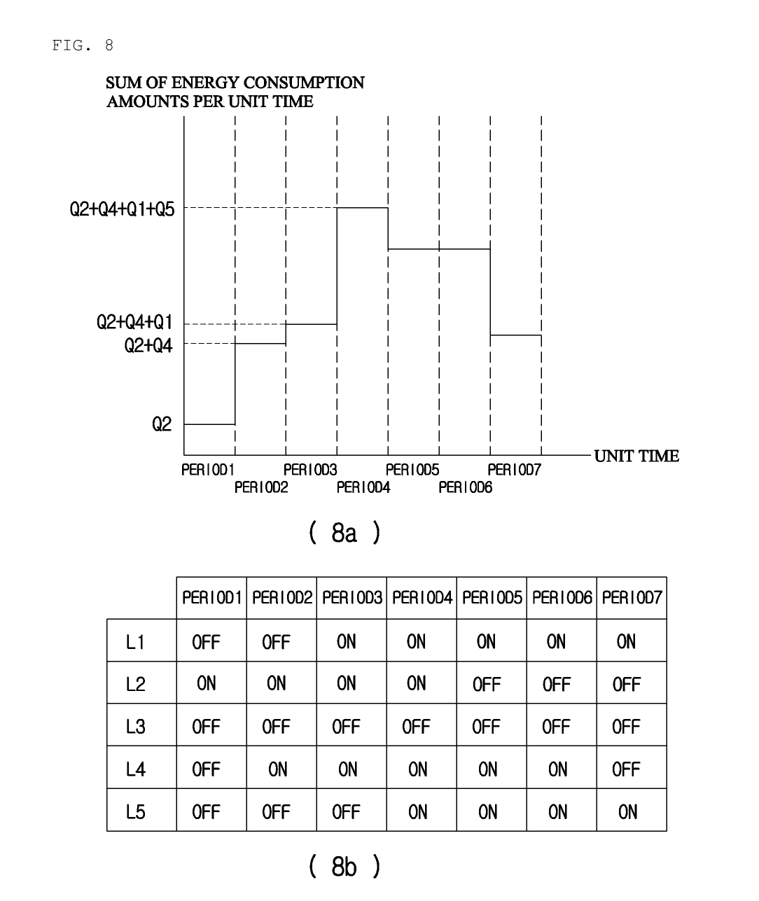

Referring to FIG. 5, when the total energy consumption amount detected at a time ‘ta’ by the meter 13 is ‘Qa’, the total energy consumption amount detected at another time ‘tb’ by the meter 13 is ‘Qb’, and ‘tb−ta’ is a unit time, the variation in the total energy consumption amount per unit time becomes ‘Qb−Qa’. In this instance, Qa>Qb. Therefore, if the value of the ‘Qb−Qa’, which is a negative (−) value, is changed into a positive (+) value, the variation in the total energy consumption amount per unit time becomes ‘Qa−Qb’.

As shown in FIG. 6, the estimation component 21 compares the ‘Qa−Qb’ with information on the previously inputted energy consumption amount per unit time for each of the electric devices (S321). Then, the estimation component 21 searches for an electric device having an energy consumption amount per unit time, corresponding to the ‘Qa−Qb’ within an error range, and estimates that the corresponding electric device is in an ON state and then changed into an OFF state at the time ‘ta’ (S322).

The estimation component 21 may transmit information that can be detected from the operating state of each of the electric devices, e.g., information on the presence of operation, operating time or the like, to the first reception components 25-1 to 25-k corresponding to the respective electric devices 16-1 to 16-k.

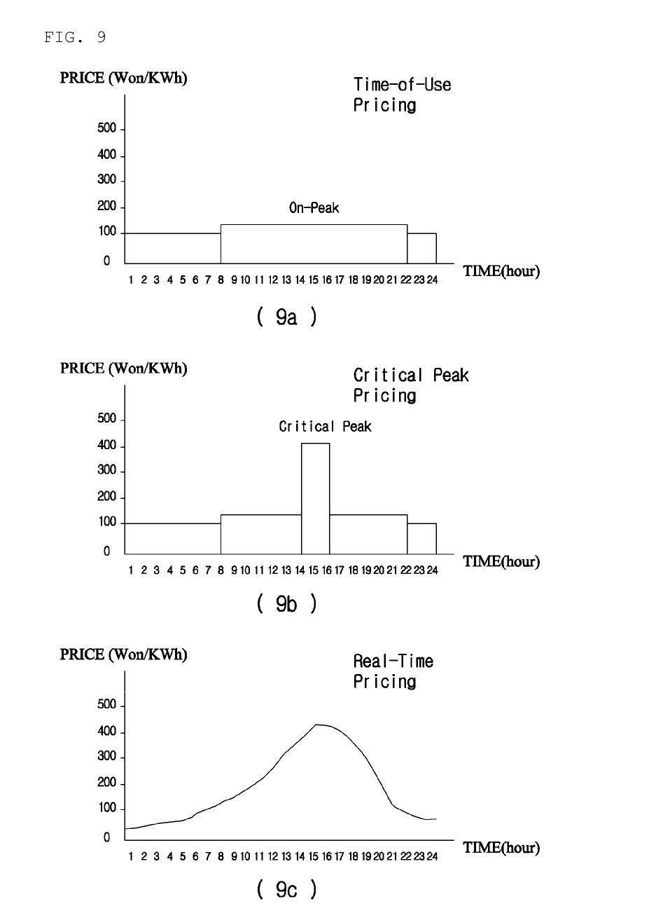

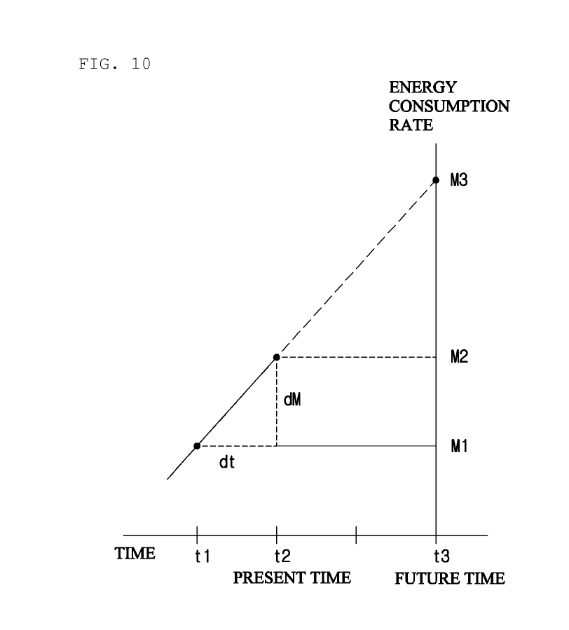

A specific example in which the estimation component 21 estimates an operating state of each of the electric devices 16-1 to 16-k will be described with reference to FIGS. 7 and 8.

FIG. 7 shows energy consumption amounts per unit time for electric devices L1 to L5. The electric devices L1 to L5 are devices that use electric energies of Q1 to Q5 per unit time, respectively.

As described above, information that the electric devices L1 to L5 are devices that use electric energies of Q1 to Q5 per unit time, respectively, may be previously inputted in the manufacture of the system, or may be inputted by the user.

FIG. 8A shows a fluctuation state of the total energy consumption amount detected by the meter 13 in each period. Here, each of the periods is a unit time period.

The total energy consumption amount per unit time in period 1 is Q2, and the total energy consumption amount per unit time in period 2 is ‘Q2+Q4’.

That is, in FIG. 8A, the variation in the total energy consumption amounts per unit time for periods 1 and 2 is Q4. Therefore, when comparing the Q4 with the previously inputted energy consumption amount per unit time for each of the electric devices, the estimation component 21 can estimate that the operating state of the electric device L4 at the starting time of period 2 has been changed from an OFF state to an ON state.

The total energy consumption amount per unit time in period 3 is ‘Q2+Q4+Q1’.

That is, in FIG. 8A, the variation in the total energy consumption amount per unit time for periods 2 and 3 is Q1. Therefore, when comparing the Q1 with the previously inputted energy consumption amount per unit time for each of the electric devices, the estimation component 21 can estimate that the operating state of the electric device L1 at the starting time of period 3 has been changed from an OFF state to an ON state.

Similarly, if the total energy consumption amount per unit time in period 5 of FIG. 8A is decreased by Q2, the estimation component 21 can estimate that the operating state of the electric device L2 at the starting time of period 5 has been changed from an ON state to an OFF state.

As described above, the estimation component 21 can estimate the operating state of each of the electric devices by comparing the variation in the total energy consumption amounts with the previously inputted energy consumption amount per unit time for each of the electric devices.

FIG. 8B shows a result obtained by estimating operating states of the electric devices L1 to L5 through the aforementioned method using the estimation component 21.

The analysis component 22 analyzes the power consumption amount of an individual electric device based on the consumption time of each of the electric devices.

Since information on the operating state of each of the electric devices is estimated through the estimation component 21 as described above, the consumption time of each of the electric devices can be detected through the information, and the power consumption amount can be analyzed using the consumption time of each of the electric devices and the energy consumption amount per unit time.

The power consumption amount refers to a total amount of power consumed by each of the electric devices. The power consumption amount may be related to a reference period in which electricity rate is calculated. For example, in a case where the electricity rate is charged every month, the power consumption amount may be an amount of power consumed by the corresponding electric device up to the present after the electricity rate is re-calculated.

The analysis component 22 may predict a current or future energy consumption rate for each of the electric devices 16-1 to 16-k based on the analyzed information on the power consumption amount and electricity price of each of the electric devices 16-1 to 16-k.

The analysis component 22 basically predicts an energy consumption rate of an individual electric device. However, if necessary, the total energy consumption rate may be predicted by summing up energy consumption rates of the individual electric device.

The second reception component 23 receives the electricity price information from the central server 15. In a case where the central server 15 performs the function of the analysis component 22 as shown in FIG. 2, the central server 15 has the electricity price information.

The electricity price may have various structures. If the energy price is fixed, the energy price information has a simple structure such as won/KWh, won/KVarh or won/KVAh.

However, the electricity price may be changed depending on an energy consumption amount or time in accumulated pricing, time of use pricing, critical peak pricing, real-time pricing, or the like.

The following table 1 shows an example of the accumulated pricing in which the unit price is increased as the energy consumption amount is increased.

TABLE 1

| | Period | | | | |
|---|---|---|---|---|---|
| | First | Second | Third | Fourth | |
| | period | period | period | period | . . . |
| Accumulated | ~100 | 101~200 | 201~300 | 301~400 | . . . |
| consumption | | | | | |
| amount [KWh] | | | | | |
| Unit price [won/KWh] | 55.10 | 113.80 | 168.30 | 248.60 | . . . |

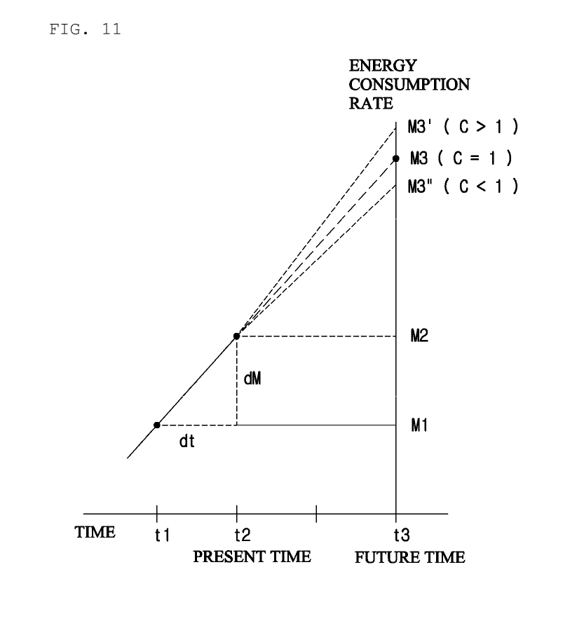

FIG. 9A shows a time of use (TOU) pricing frequently used in arcades, factories, large-scale buildings, in which the price of electricity is changed depending on time zone. FIG. 9B shows a critical peak pricing (CPP) in which the price of electricity is changed depending on time zone, and particularly, the price of electricity in a peak period is very high. FIG. 9C shows a real-time pricing (RTP) in which the price of electricity is changed in real time.

The analysis component 22 may predict a current energy consumption rate of an individual electric device using the following equation 1.

$$M ( k ) = {Q}_{i = 1} [ Q ( k , i ) sP ( i ) ] \qquad [ Equation 1 ]$$

where, ‘k’ denotes a variable for distinguishing electric devices, ‘i’ denotes a variable for distinguishing unit times at which an electric device #k is under operation, M(k) denotes an energy consumption rate for the electric device #k, Q(k, i) denotes an energy consumption amount in a time period ‘i’, and P(i) denotes an electricity price in the time period ‘i’.

The total energy consumption rate MT for all the electric devices may be predicted by the following equation 2.

$$MT = {{Q}^{n}}_{k = 1} M ( k ) \qquad [ Equation 2 ]$$

where, ‘n’ denotes a number of electric devices, ‘k’ denotes a variable for distinguishing electric devices, and M(k) denotes an energy consumption rate for the electric device #k.

The analysis component 22 may calculate energy consumption rates of an individual electric device or total energy consumption rates of the electric devices at minimum two times through the equations 1 and 2 and predict a future energy consumption rate based on the variation rate in the calculated energy consumption rate.

Here, the future time intended to predict the energy consumption rate may be set to a unit such as a day, week, month or year, or may be set to a specific future time. In the latter case, the specific future time may be a time, e.g., the last day in each month, specified so that the user settles the energy consumption rate.

The method for predicting a future energy consumption rate using the analysis component 22 may be variously configured. Particularly, the future energy consumption rate may be predicted using a primary linear function or using a secondary or higher-order non-linear function.

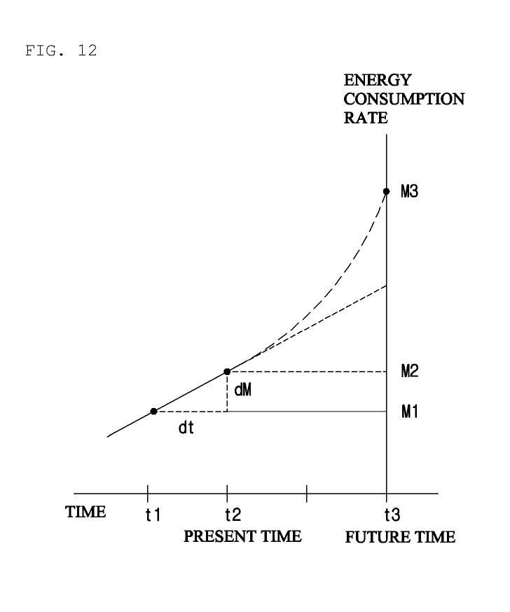

Various methods for estimating a future energy consumption rate using the analysis component 22 will be described with reference to FIGS. 10 to 13.

It is assumed that the energy consumption rate (the energy consumption rate of an individual electric device or the total energy consumption rate of electric devices) at a past time t1 is M1, the energy consumption rate at a current time t2 after a certain time elapses from the past time t1 is M2, and the energy consumption rate at a future time, intended to predict, is M3.

Then, the variation in the energy consumption rate may be calculated as dM, and the variation rate in the energy consumption rate may be calculated as ‘dM÷dt’, where, dM is ‘M2−M1’, and dt is ‘t2−t1’.

FIG. 10 shows an example using a linear method so as to predict a future energy consumption rate. The energy consumption rate M3 at the future time t3 may be predicted by the following equation 3.

$$M 3 = M 2 + \frac{d M}{d t} s ( t 3 - t 2 ) \qquad [ Equation 3 ]$$

FIG. 11 shows an example using a weighted value so as to predict a future energy consumption rate. The method using the weighted value may be variously configured.

A method may be used as one example, in which a weighted value ‘C’ is applied to a value greater than 1, a value of 1, or a value smaller than 1 according to the variation rate in the energy consumption rate.

In this instance, the energy consumption rate M3 at the future time t3 may be predicted by the following equation 4.

$$M 3 = M 2 + Cs \frac{d M}{d t} s ( t 3 - t 2 ) \qquad [ Equation 4 ]$$

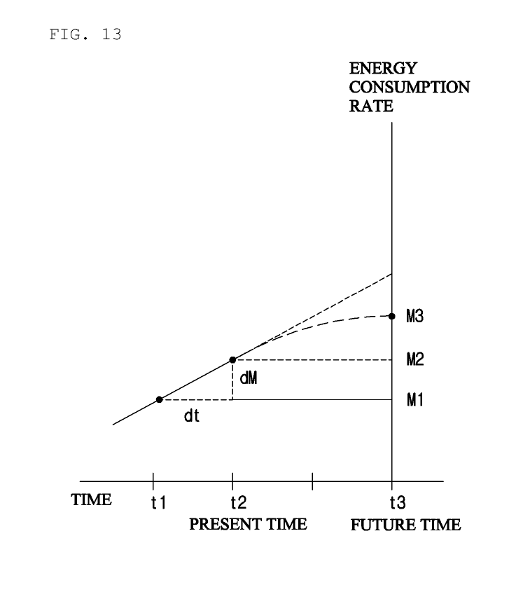

FIG. 12 shows an example using an exponential curve so as to predict a future energy consumption rate. The energy consumption rate M3 at the future time t3 may be predicted by the following equation 5.

M3=M2+(e^{a(t3-t2)}−1) [Equation 5]

where, ‘a’ may be determined based on the accumulated pricing of the electricity price or the variation rate in the energy consumption rate.

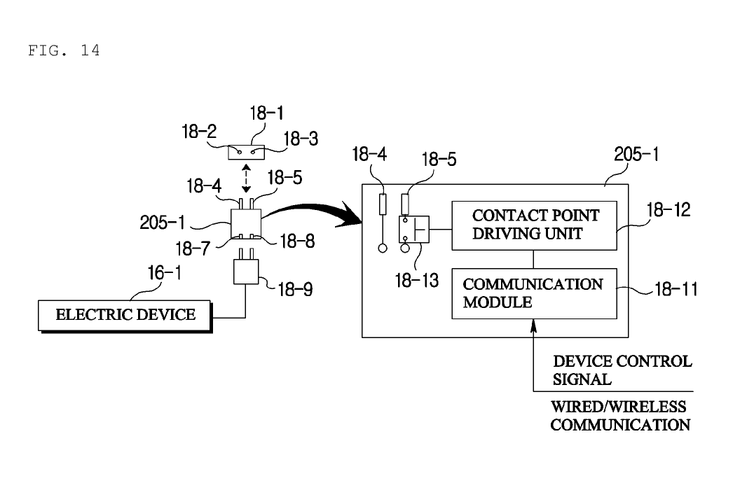

FIG. 13 shows an example using a logarithmic curve so as to predict a future energy consumption rate. The energy consumption rate M3 at the future time t3 may be predicted by the following equation 6.

M3=M2+ln(a(t3−t2)+1) [Equation 6]

where, ‘a’ may be determined based on the accumulated pricing of the electricity price or the variation rate in the energy consumption rate.

The analysis component 22 may predict a rate to be actually charged to the user based on the current or future energy consumption rate using information on the rate imposition policy of the electric power company 11.

The information on the rate imposition policy of the energy supply company 11 may basically include a basis rate, a tax, a power factor rate, a rate benefit, and the like.

The tax may include a value-added tax, various funds, and the like. The rate benefit means that a specific industry, e.g., a knowledge service industry has a cheaper power rate than other industries. As a specific example, the rate actually charged to the user may be calculated as ‘power rate+additional rate’.

In this instance, the power rate may be calculated as ‘power consumption amount×unit price+basis rate’, and the additional rate may be calculated as ‘electric power industry basis fund+added-value tax’. The electric power industry basis fund may be set as 3.7% of the power rate, and the added-value tax may be set as 10% of the power rate.

Here, the ‘power consumption amount×unit price’ that determines the power rate is a value predicted through the equations 1 to 6.

The analysis component 22 may predict the lifespan of an individual electric device by analyzing the consumption time or efficiency of the individual electric device.

For example, the analysis component 22 may predict a remaining lifespan by comparing the lifespan of each of the electric devices, inputted in advance or inputted by the user with the consumption time of an individual electric device detected by the estimation component 21.

The analysis component 22 transmits various pieces of analyzed energy related information, e.g., the power consumption amount, remaining lifespan, current energy consumption rate and future energy consumption rate of an individual electric device, to the first reception components 25-1 to 25-k respectively corresponding to the electric devices 16-1 to 16-k.

The analysis component 22 may be configured to monitor whether or not the predicted energy consumption rate or total energy consumption rate exceeds a maximum value set by the user.

In this embodiment, the analysis component 22 may provide a user interface (UI) that enables the user to set maximum value information, or may receive the maximum value information set by the user from another device.

If the predicted energy consumption rate or total energy consumption rate exceeds the maximum value, the analysis component 22 may transmit a warning message to a user's portable terminal, an in home display (IHD), or the like.

In this instance, the analysis component 22 may transmit the warning message through various communication interfaces such as a near field communication network or Internet network. Particularly, the analysis component 22 may transmit the warning message to a user's cellular phone through a mobile communication network.

The first reception components 25-1 to 25-k, the display components 26-1 to 26-k), and the switch components 205-1 to 205-k are provided to correspond to the respective electric devices 16-1 to 16-k.

If various pieces of energy related information detected by the estimation component 21 and the analysis component 22, e.g., the consumption time, power consumption amount, remaining lifespan, current energy consumption rate and future energy consumption rate of an individual electric device, are transmitted through wired and wireless communication schemes, the various pieces of energy related information are received by the first reception components 25-1 to 25-k provided to correspond to the respective electric devices 16-1 to 16-k.

The first reception components 25-1 to 25-k transfer the energy related information received by the estimation component 21 and the analysis component 22 to the respective display components 26-1 to 26-k. Each of the display components 26-1 to 26-k visually outputs the energy related information on a display screen so as to enable the user to identify energy related information of an individual electric device.

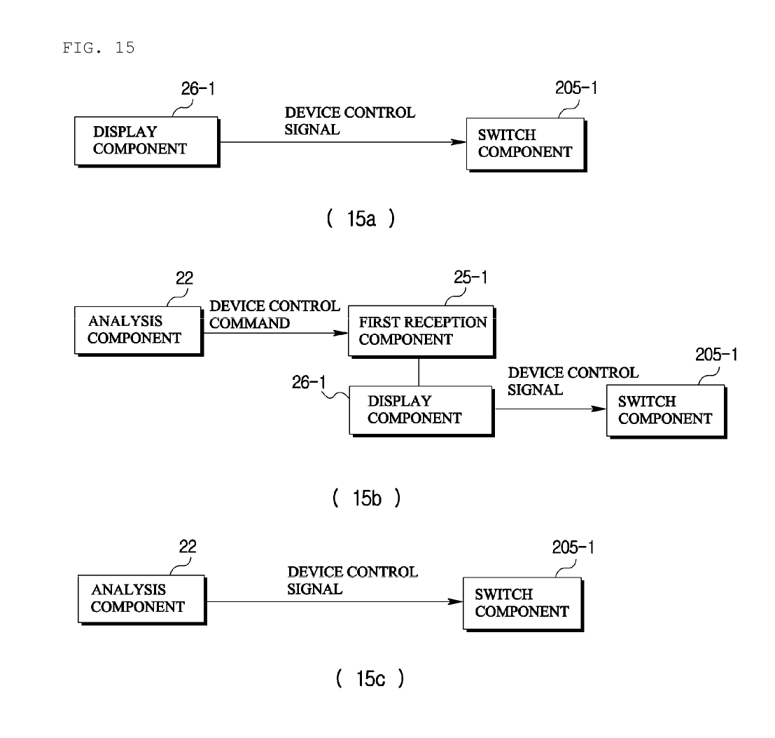

FIG. 14 shows an embodiment of the switch component 205-1 to which a power plug 18-9 of the electric device 16-1 is connected. The power plug 18-9 of the electric device 16-1 is connected to an outlet 18-1 through the switch component 205-1.

The switch component 205-1 may be configured to have a wall outlet or fastening pins 18-4 and 18-5 capable of being attached/detached to/from fastening holes 18-2 and 18-3 of the multi-outlet 18-1 connected to the wall outlet. The switch component 205-1 may also be configured to have fastening holes 18-7 and 18-8 capable of being connected to the power plug 18-9 of the electric device.

A communication module 18-11 of the switch component 205-1 receives a device control signal and transfers the received device control signal to a contact point driving unit 18-12. The contact point driving unit 18-12 connects or opens a contact point 18-13 for power of the corresponding electric device.

The switch component 205-1 may be provided to the inside of an electric device.

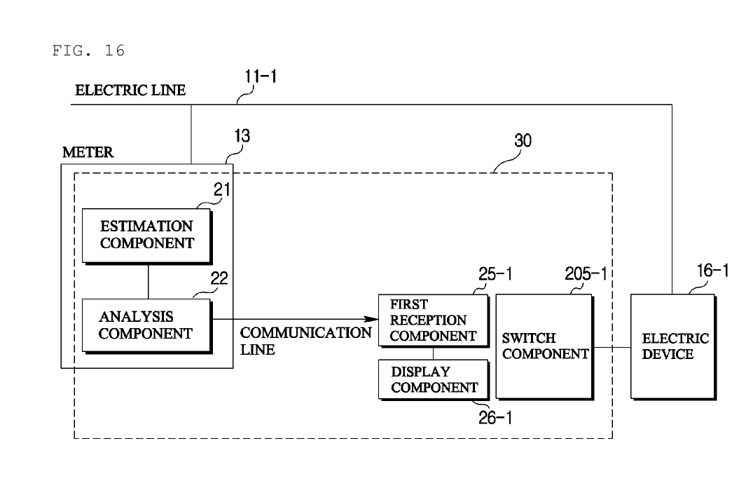

FIG. 15 shows various examples of the path along which a device control signal is transferred to the switch component 205-1.

FIG. 15A shows an example in which the display component 26-1 directly controls the switch component 205-1. The display component 26-1 displays energy related information received from the estimation component 21 and the analysis component 22 on a display screen.

The display component 26-1 determines whether or not to control the switch component 205-1 using the energy related information. Then, the display component 26-1 controls an ON/OFF state of a corresponding electric device by transferring a device control signal to the switch component 205-1 based on the corresponding determination.

FIG. 15B shows an example in which the analysis component 22 indirectly controls the switch component 205-1. The analysis component 22 determines whether or not to control the switch component 205-1 using the analyzed energy related information, and transmits a device control signal to a corresponding electric device based on the corresponding determination.

Then, the first reception component 25-1 of the corresponding electric device receives the device control signal and transfers the received device control signal to the display component 26-1. The display component 26-1 transfers the device control signal to the switch component 205-1. That is, the display component 26-1 performs only the function of transferring the device control signal related to the control of the switch component 205-1.

In the example of FIG. 15B, the first reception component 25-1 may not transfer the device control signal to the switch component 205-1 via the display component 26-1 but directly transfer the device control signal to the switch component 205-1.

FIG. 15C shows an example in which the analysis component 22 directly controls the switch component 205-1. The analysis component 22 determines whether or not to control the switch component 205-1 using the analyzed energy related information, and directly transmits a device control signal to the switch component 205-1 based on the corresponding determination.

Meanwhile, if necessary, it may be variously configured in which case the analysis component 22 or the display unit 26-1 will control each of the switch components 205-1 to 205-k of the electric devices. As a specific example, if specific energy related information exceeds a predetermined maximum value, a corresponding switch component may be controlled to be in an OFF state.

That is, the user may determine a maximum value on electricity price, power consumption amount, current energy consumption rate, future energy consumption rate or the like for each of the electric devices. If the electricity price, power consumption amount, current energy consumption rate, future energy consumption rate or the like exceeds the determined maximum value, the power of the corresponding electric device may be cut off.

The current energy consumption rate, future energy consumption rate or the like may be a total value on the electric devices. If the total value exceeds a maximum value, it is necessarily selected which electric device will be in an OFF state.

In this case, it may be variously configured, if necessary, which electric device will be selected as an object to be controlled. For example, a sequence control method or priority control method may be used.

The sequence control method is a method of sequentially control electric devices. In the sequence control method, the supply of energy is first restarted to the electric device of which energy supply was first stopped.

The priority control method is a method of deciding priorities of electric devices according to the importance degree of each of the electric devices. In the priority control method, the energy supply of the electric device having the lowest priority is first stopped, and the energy supply of the electric device having the highest priority is first restarted. That is, the supply of energy is first restarted to the electric device of energy supply was stopped at the end.

In this instance, the priority of each of the electric devices may be variously determined using a method of allowing a user to directly specifying the priority as a device control schedule, a method of determining the priority to be low as its energy efficiency is deteriorated, a method of determining the priority to be low as its energy consumption rate is increased, and the like.

If the control of an electric device is performed, the analysis component 22 or the display component 26-1 transmits the control result to the user's portable terminal or IHD so as to inform the user of the control result.

In this case, the analysis component 22 or the display component 26-1 may transmit the corresponding information through various communication interfaces. Particularly, the analysis component 22 or the display component 26-1 may transmit the corresponding information to a user's cellular phone through a mobile communication network.

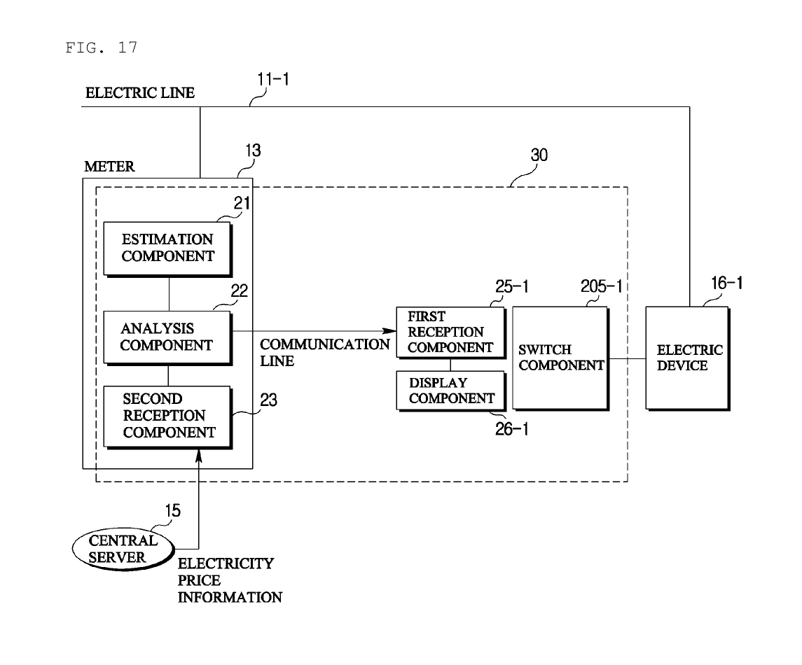

FIG. 16 shows an embodiment of an apparatus 30 for energy management according to the present invention. The apparatus 30 includes at least an estimation component 21, an analysis component 22, a first reception component 25-1, a display component 26-1 and a switch component 205-1.

Although only one first reception component 25-1, one display component 26-1 and one switch component 205-1 are illustrated for convenience of illustration, the first reception component 25-1, the display component 26-1 and the switch component 205-1 are provided to correspond to each of the electric devices 16-1 to 16-k.

The first reception component 25-1 and the display component 26-1 may be configured as a single device attached to an outside or circumference of the electric device 16-1. The device may be configured to be attachable/detachable. The switch component 205-1 may be integrally configured with the corresponding device or may be configured as a separate device.

As shown in FIG. 17, the apparatus 30 may further include a second reception component 23 that receives electricity price information according to time from the central server 15.

The functions of the estimation component 21 and the analysis component 22, which constitute the apparatus 30, may be performed in the meter 13.

The estimation component 21, the analysis component 22, the second reception component 23, the first reception component 25-1, the display component 26-1 and the switch component 205-1, which constitute the apparatus 30, perform functions identical to those of the aforementioned apparatus, and therefore, overlapping descriptions will be omitted.

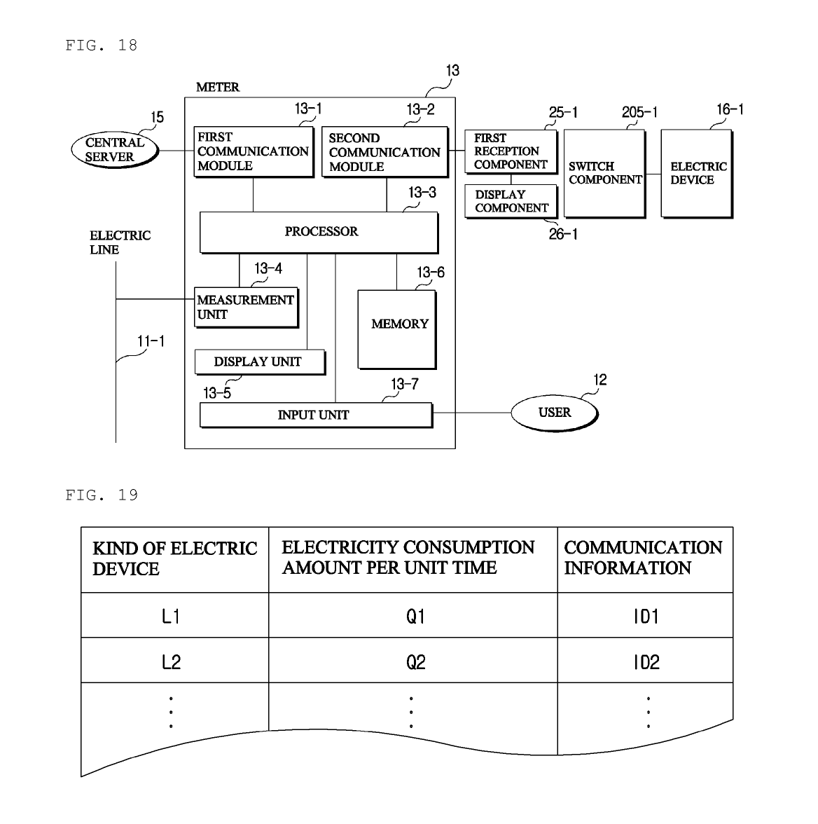

A specific embodiment of the meter 13 that performs the functions of the estimation component 21 and the analysis component 22 in the apparatus 30 will be described with reference to FIG. 18.

A first communication module 13-1 communicates with the central server 15, and a second communication module 13-2 transmits energy related information to each of the electric devices 16-1 to 16-k.

A measurement unit 13-4 detects consumption information of electric energy that flows in the electric line 11-1, e.g., a total energy consumption amount or the like.

A display unit 13-5 visually displays various pieces of information related to the operation of the meter 13.

An input unit 13-7 enables the user to input command or information related to the operation of the meter 13 through various input devices such as a key button and a touch screen.

A driving program and data necessary for the operation of the meter 13 are stored and maintained in a memory 13-6. The driving program includes a program that enables the meter 13 to perform the functions of the estimation component 21, the analysis component 22, the second reception component 23 and the like.

The memory 13-6 stores energy consumption amount information per unit time for each of the electric devices, information for communicating with the first reception components 25-1 to 25-k corresponding to the respective electric devices.

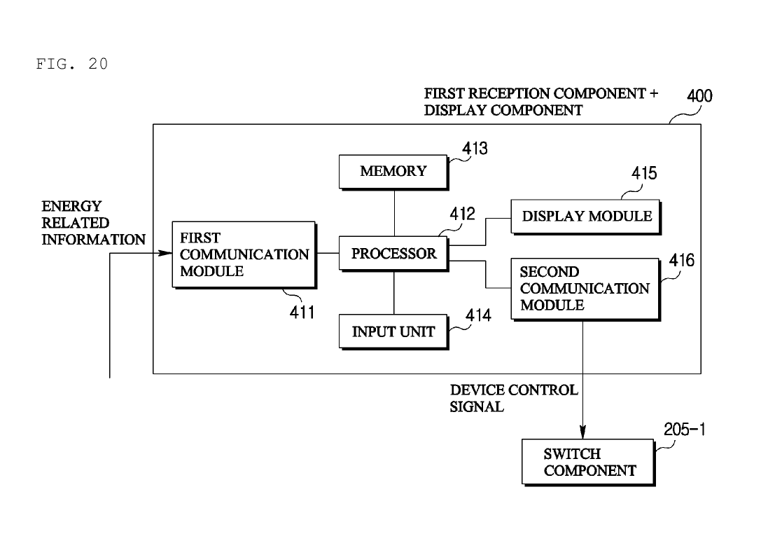

FIG. 19 shows an example of information stored in the memory 13-6. According to the kind of each of the electric devices, energy consumption amount information per unit time for the corresponding electric device and communication information for transmitting energy related information to each of the electric device are shown in FIG. 19. The communication information may contain a unique identification (ID) for each of the electric devices.

The information may be previously stored in the memory 13-6 in the manufacture of the apparatus or may be inputted through the input unit 13-7 by the user 12.

A processor 13-3 generally controls the operation of the meter 13, and may be a microprocessor or central processing unit (CPU).

If the driving of the meter 13 is started, the processor 13-3 controls the meter 13 according to the driving program stored in the memory 13-6 so that the meter 13 operates based on each of the embodiments of the apparatus 30 according to the present invention.

That is, the processor 13-3 estimates an operating state of an individual electric device using information on the total energy consumption amount detected by the measurement unit 13-4, and analyzes various pieces of energy related information, such as the consumption time, power consumption amount, remaining lifespan, current energy consumption rate and future energy consumption rate of the individual electric device, using the estimated information and the electricity price information received from the central server 15 through the first communication module 13-1. Then, the processor 13-3 transmits the analyzed energy related information to each of the electric devices through the second communication module 13-2.

If the analysis component 22 controls the switch component 205-1 as described with reference to FIG. 15B or 15C, information necessary for controlling the electric devices is stored in the memory 13-6, such as a maximum value on electricity price, power consumption amount, current energy consumption rate and future energy consumption rate, a control method (e.g., a sequence control method, priority control method, or the like), efficiency information of each of the electric devices and a device control schedule. The user 12 may set the information through the input unit 13-7.

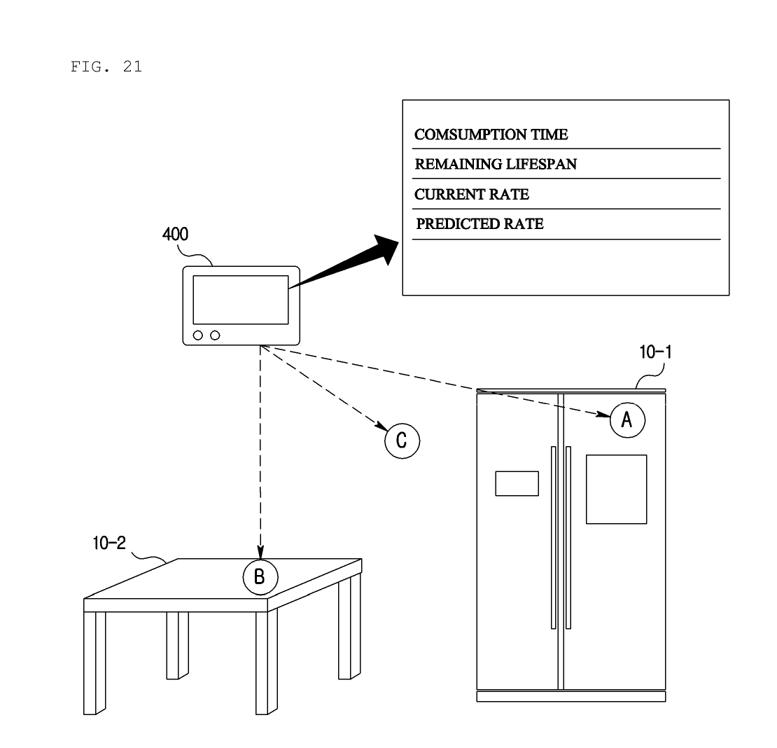

FIG. 20 shows a specific example of an apparatus 400 that performs the function of the first reception component 25-1 and the display component 26-1. The apparatus 400 may include a first communication module 411, a processor 412, a memory 413, an input unit 414, a display module 415, a second communication module 416, and the like.

The processor 412 generally controls the apparatus 400 by operating based on a driving program stored in the memory 413.

That is, the processor 412 receives and processes energy related information transmitted through the first communication module 411 by the meter 13 and then transfers the energy related information to the display module 415, so that the display module 415 visually displays the energy related information.

In a case where the display component 26-1 directly controls the switch component 205-1 as described with reference to FIG. 15A, the apparatus 400 determines whether or not to control the switch component 205-1 based on the energy related information received through the first communication module 414 and then transfers a device control signal through the second communication module 416.

In this instance, the information necessary for controlling an individual electric device, such as a maximum value on the electricity price, power consumption amount, current energy consumption rate or future energy consumption rate, may be inputted through the input unit 414 from the user so as to store the information in the memory 413.

For example, it is assumed that the user sets the maximum value on the energy consumption rate of a corresponding electric device as 5000 won through the input unit 414. In a case where the current energy consumption rate exceeds 5000 won in the energy related information received through the first communication module 411, the processor 412 transfers a device control signal for cutting off power to the switch component 205-1 through the second communication module 416.

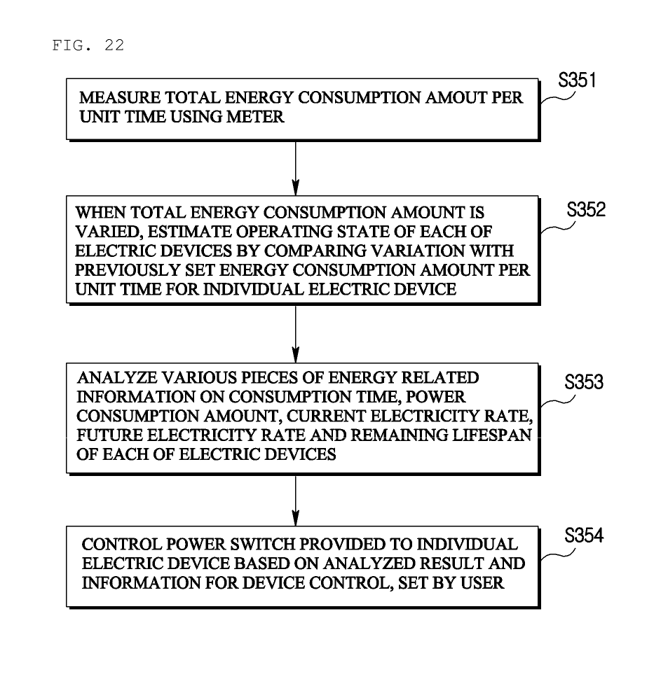

FIG. 21 shows a state that the apparatus 400 of FIG. 20 is attached to an outside or circumference of a refrigerator 10-1 for better understanding of illustration.

Various pieces of energy related information are outputted on a screen of the apparatus 400. The energy related information includes consumption time, remaining lifespan, current energy consumption rate and future energy consumption rate of the refrigerator 10-1 that is an electric device corresponding to the apparatus 400.

The apparatus 400 may be fixed to an outside or circumference of each of the electric devices, or may be freely attachable/detachable.

For example, the apparatus 400 may be attached not only to an outer case A of an electric device such as the refrigerator 10-1 but also to a circumference of the corresponding electric device such as a top surface B of a table 10-2 positioned in the vicinity of the electric device or a wall surface C positioned in the vicinity of the electric device. The apparatus 400 may be configured to be freely attachable/detachable.

The apparatus 400 may display various pieces of energy related information such as information on the presence of operation or operating time of the corresponding electric device, electricity consumption amount of the corresponding electric device in a unit time period, transmitted by the analysis component 22, accumulated power consumption amount of the corresponding electric device, excess state of a maximum value and electricity price information according to time.

The information may be displayed through various techniques including simple characters, images, graphics, graphs, moving pictures, and the like. It will be apparent that the information may be displayed together with other additional information that helps user's rational energy consumption.

A specific embodiment of a method for energy management according to the present invention will be described with reference to FIG. 22.

First, the meter measures a total energy consumption amount per unit time (S351).

A smart meter may be used as the meter.

If the total energy consumption amount is varied as the result measured at the operation S351, the apparatus estimates an operating state of an individual electric device by comparing the variation with the previously inputted energy consumption amount per unit time for each of the electric devices (S352).

That is, at the operation S352, if the total energy consumption amount per unit time, measured by the meter, is varied as described with reference to FIGS. 3 to 8, the apparatus compares the corresponding variation with the previously inputted energy consumption amount information per unit time for each of the electric devices, and detects an electric device of energy consumption amount corresponds to the variation within an error range.

In a case where the variation of the total energy consumption amount per unit time is positive (+), it is estimated that the state of the corresponding electric device is changed from an OFF state to an ON state. In a case where the variation of the total energy consumption amount per unit time is negative (−), it is estimated that the state of the corresponding electric device is changed from an ON state to an OFF state.

In this instance, the information on the energy consumption amount per unit time for each of the electric devices may be previously inputted in the manufacture of the system, or may inputted by a user.

If the operating state of each of the electric devices is estimated at the operation S352, the consumption time of each of the electric devices can be detected.

Then, the apparatus analyzes various pieces of energy related information such as power consumption amount, current electricity rate, future electricity rate and remaining lifespan of each of the electric devices, using the consumption time of each of the electric devices (S353)

If the energy related information is analyzed at the operation S353, the apparatus transmits the energy related information to each of the electric devices so as to visually display the energy related information at an outside or circumference of an individual electric device, and controls a power switch provided to each of the electric devices based on the analyzed result (S354).

The energy related information may be transmitted through various wireless communication schemes such as RF, Zigbee and Bluetooth, or may be transmitted through a wired communication scheme using a general electric line, electric power line, local area network (LAN) cable, telephone line, or the like.

Hereinafter, the various pieces of energy related information analyzed at the operation S353 will be described.

First, the power consumption amount of an individual electric device may be analyzed based on the consumption time of each of the electric devices at the operation S353.

That is, since the operating state of each of the electric devices is estimated at the operation S352, the consumption time of each of the electric devices may be detected through the energy related information, and the power consumption amount of each of the electric devices may be analyzed using the consumption time and energy consumption amount per unit time for each of the electric devices.

Then, the current energy consumption rate for an individual electric device may be estimated based on the power consumption amount and electricity price information.

To this end, the operation S353 may further include an operation of receiving electricity price information according to time from the central server.

At the operation S353, the current energy consumption rate of an individual electric device may be basically predicted as described through the equation 1. However, if necessary, the total energy consumption rate may be predicted by summing up energy consumption rates of the individual electric device as described through the equation 2.

At the operation S353, the future energy consumption rate of each of the electric devices may be predicted based on the power consumption amount information and the electricity price information using a primary linear function or using a secondary or higher-order non-linear function as described through the equations 3 to 6.

At this instance, the rate to be actually charged to the user may be predicted as a current or future energy consumption rate using information on the rate imposition policy of the electric power company.

At the operation S353, the lifespan of an individual electric device may be predicted through the consumption time or efficiency analysis of the individual electric device.

At the operation S353, it may be configured to monitor whether or not the estimated individual energy consumption rate or total energy consumption rate exceeds a maximum value set by the user.

If the estimated individual energy consumption rate or total energy consumption rate exceeds the maximum value, a warning message may be transmitted to a user's portable terminal, IHD or the like.

Meanwhile, at the operation S354, an apparatus attached to an outside or circumference of an individual electric device, e.g., the apparatus described with reference to FIG. 20, receives the energy related information and visually displays the energy related information on a display screen, and controls the power switch of the electric device by determining whether or not it is required to control the electric device.

The apparatus that receives the energy related information and visually display the energy related information is provided to correspond to each of the electric devices. The apparatus may be fixed to each of the electric devices, or may be freely attachable/detachable.

At the operation S354, it may be variously configured, if necessary, in which case the switch component of each of the electric devices will be controlled.

As a specific example, if various pieces of energy related information exceeds a predetermined maximum value, the power switch may be controlled to be in an OFF state.

That is, the user may determine a maximum value on electricity price, power consumption amount, current energy consumption rate, future energy consumption rate or the like for each of the electric devices. If the electricity price, power consumption amount, current energy consumption rate, future energy consumption rate or the like exceeds the determined maximum value, the power switch of the corresponding electric device may be turned off.

At the operation S354, in a case where the control for each of the electric devices is performed, the result may be transmitted to the user's portable terminal, IHD or the like so as to be informed to the user.

As described above, according to embodiments of the present invention, it is possible to detect the operating state of each electric device by comparing an energy consumption amount per unit time, detected by a meter with a previously inputted energy consumption amount per unit time for each of the electric devices.

If the operating state of each of the electric devices is detected, information on the consumption time and electricity consumption amount of each of the electric devices can be obtained. Thus, it is possible to predict a current or future energy consumption rate within a rational range using electricity price information according to time.

Since energy related information such as electricity consumption amount, current energy consumption rate and future energy consumption amount is displayed corresponding to each of the electric devices, a user can easily identify the energy consumption state of an individual electric device.

If the energy related information is displayed for each of the electric devices, it is possible to realize energy consumption situation of each of the electric devices and to help the user determine his/her intention of selecting electric devices to be operated and electric devices to be stopped.

If the current or future energy consumption rate is predicted, the energy consumption of an energy consumption device is controlled to be performed within a limited range by turning on/off the energy consumption device according to the predicted result, so that energy can be more effectively used.

Although the present invention has been described in connection with the preferred embodiments, the embodiments of the present invention are only for illustrative purposes and should not be construed as limiting the scope of the present invention. It will be understood by those skilled in the art that various changes and modifications can be made thereto within the technical spirit and scope defined by the appended claims.

What is claimed is:

1. An apparatus for energy management of electric devices, the apparatus comprising:
an energy related information display component attached to an outside or circumference of an individual electricity device;
an estimation component configured to estimate an individual energy consumption amount based on an energy variation depending on time using a meter;
an analysis component configured to analyze a power consumption amount of the individual electric device by analyzing a consumption time of the individual electric device;
a first reception component through which the energy related information display component attached to the outside or circumference of the individual electric device receives individual energy related information of the individual electric device from the estimation component and the analysis component; and
a switch component configured to determine whether or not an electric device is operated in the vicinity of the energy related information display component.

2. The apparatus of claim 1, further comprising a second reception component configured to receive electricity price information according to time from a central server.

3. The apparatus of claim 1, wherein the meter comprises a smart meter.

4. The apparatus of claim 3, wherein the smart meter stores energy consumption amount information of the individual electric device in a memory.

5. The apparatus of claim 1, wherein functions of the estimation component and the analysis component are performed in the smart meter or the central server.

6. The apparatus of claim 1, wherein the analysis component predicts at least one of current and future energy consumption rates of the individual electric device.

7. The apparatus of claim 1, wherein the analysis component predicts the lifespan of the individual electric device.

8. The apparatus of claim 1, wherein the individual energy related information of the individual electric device is communicated through a wireless communication scheme.

9. The apparatus of claim 8, wherein the wireless communication scheme comprises at least one of RF, Zigbee and Bluetooth communication schemes.

10. The apparatus of claim 1, wherein the individual energy related information of the individual electric device is communicated through a wired communication scheme.

11. The apparatus of claim 10, wherein the wired communication scheme is performed using at least one of a general electric line, a power line, a LAN cable and a telephone line.

12. The apparatus of claim 1, wherein the energy related information display component is positioned in the vicinity of an on/off switch of the individual electric device.

13. A method for energy management of electric devices, the method comprising:
displaying energy related information at an outside or circumference of an individual electricity device;
estimating an individual energy consumption amount based on an energy variation depending on time using a meter;
analyzing a power consumption amount of the individual electric device by analyzing a consumption time of the individual electric device;
receiving individual energy related information of the individual electric device from the estimating and the analyzing in the displaying of the energy related information at the outside or circumference of the individual electric device; and
determining whether or not an electric device is operated in the vicinity of the energy related information display component.

14. The method of claim 13, further comprising receiving electricity price information according to time from a central server.

15. The method of claim 13, wherein the estimating and the analyzing are performed in a smart server or the central server.

16. The method of claim 13, wherein the analyzing predicts at least one of current and future energy consumption rates of the individual electric device.

17. The method of claim 13, wherein the analyzing predicts the lifespan of the individual electric device.

18. The method of claim 13, wherein the individual energy related information of the individual electric device is communicated through a wireless communication scheme.

19. The method of claim 18, wherein the wireless communication scheme comprises at least one of RF, Zigbee and Bluetooth communication schemes.

20. The method of claim 13, wherein the individual energy related information of the individual electric device is communicated through a wired communication scheme.
